(19) United States
(12) Patent Application Publication
(10) Pub. No.: US 2015/0162473 A1
(43) Pub. Date: Jun. 11, 2015

(54) DEVICES FOR THERMAL MANAGEMENT OF PHOTOVOLTAIC DEVICES AND METHODS OF THEIR MANUFACTURE

(71) Applicant: Christopher J. Rothfuss, Laramie, WY (US)

(72) Inventors: Sung-Wei Chen, Las Vegas, NV (US); Christopher J. Rothfuss, Laramie, WY (US)

(73) Assignee: EMPIRE TECHNOLOGY DEVELOPMENT LLC, Wilmington, DE (US)

(21) Appl. No.: 13/879,544

(22) PCT Filed: Aug. 16, 2012
(86) PCT No.: PCT/US12/51036

§ 371 Date: Dec. 6, 2014

(30) Foreign Application Priority Data
Feb. 17, 2011 (DE) 10-2011-011-610.
Dec. 5, 2011 (DE) 10-2011-120.068.5

(51) Int. Cl. H01L 31/052; H02S 40/42

(52) U.S. Cl. CPC H01L 31/052; H02S 40/42

(57) ABSTRACT

A device for managing the heat load of one or more photovoltaic cells and methods for fabricating and using the device are disclosed. The device may include a base unit and an overhang unit that overhangs at least a portion of the base unit. The overhang unit may also be in thermal communication with the base unit. One or more photovoltaic cells may be in thermal communication with the base unit, and the overhang unit may overhang the photovoltaic cells as well. The overhang unit may be composed of a material that may reduce the amount of radiation having energy less than the band-gap energy from reaching the cells. The device may also include an upright section between the base unit and the overhang unit that is in thermal communication with both the base and the overhang.

### BACKGROUND

Low cost improvements to photovoltaic (PV) cell efficiency are essential for growing the solar power market. The peak efficiency for high dollar crystalline silicon PV cells has now surpassed 40%, but the general consumer solar market may still produce cells with efficiencies ranging from 10% to 25% depending on technology and cost. The vast majority of the unutilized solar potential energy (75-90%) may be converted to heat in the solar cell and should be dissipated. This heat may result in shorter cell lifetimes and lower cell efficiencies. A wide review of silicon based solar cells shows that a 30° C. increase in operating temperature may reduce cell power output by about 14%. Similarly, a 50° C. increase in temperature (which may not be unreasonable without thermal management) may reduce cell power output by about 23%. Overall, each 1° C. increase in PV cell operating temperature may result in a 0.45% decrease in power output.

Numerous thermal management approaches may exist for high cost solutions (e.g. for solar farms) where cooling systems may be attached to the backs of the solar cells to dissipate heat. This may not generally be an ideal solution, as the geometry may reduce natural convection. With sufficient materials and costs (and sometimes parasitic active cooling), the PVs may be cooled within reasonable operating parameters for these applications. However, this approach may not be acceptable for the developing mainstream PV market that may include PV “roofing tiles” and “roll to roll” photovoltaics. The price point of such commercial PV devices may be too low to include thermal management technology. Additionally, roof-tops—on which the mainstream PV products are frequently deployed—tend to be designed to minimize heat transfer to the roof, rather than to facilitate it. It is therefore desirable to develop a low cost means of thermal management of photovoltaic cells to improve their efficiency in their use in the mainstream commercial market.

### SUMMARY

In an embodiment, a device for managing heat in at least one photovoltaic cell may include a base component having a top surface and in thermal communication with at least a portion of at least one photovoltaic cell, and an overhang component in thermal communication with the base component, in which the overhang component may be disposed above and project over at least a portion of the top surface of the base component.

In an embodiment, a method of thermal management of at least one photovoltaic cell may include providing at least one photovoltaic cell, providing at least one thermal management device that includes a base component having a top surface and an overhang component in thermal communication with the base component, causing at least a portion of the at least one photovoltaic cell to form a thermal contact with the thermal management device, having the overhang component disposed above and projecting over at least a portion of the at least one photovoltaic cell, and exposing the thermal management device to a fluid thereby transferring an amount of heat from the thermal management device to the fluid.

In an embodiment, a method of fabricating a thermal management device for at least one photovoltaic cell includes providing a first heat conducting material, providing a second heat conducting material substantially transparent to a radiation having an energy greater than about a band-gap energy of the at least one photovoltaic cell and substantially opaque to a radiation having an energy less than about the band-gap energy of the at least one photovoltaic cell, fabricating a base component having a top surface from the first heat conducting material, the second heat conducting material, or a combination of the first and second heat conducting materials, fabricating an overhang component from the second heat conducting material, thermally contacting the overhang component with the base component, and disposing the overhang component above and over at least a portion of the top surface.

In an embodiment, a method of fabricating a thermal management device for at least one photovoltaic cell includes providing a heat conducting material substantially transparent to a radiation having an energy greater than about a band-gap energy of the at least one photovoltaic cell and substantially opaque to a radiation having an energy less than about the band-gap energy of the at least one photovoltaic cell, and fabricating a combined base component having a top surface and overhang component from the material, in which the overhang component is disposed above and over at least a portion of the top surface.

In an embodiment, a method of fabricating a thermal management device for at least one photovoltaic cell may include providing a heat conducting material substantially transparent to a radiation having an energy greater than about a band-gap energy of the at least one photovoltaic cell and substantially opaque to a radiation having an energy less than about the band-gap energy of the at least one photovoltaic cell, and fabricating a combined base, upright, and overhang component from the material, in which the base component may have a top surface and the upright component may be in thermal communication with the base component and/or the overhang component, in which the overhang component may be disposed above and over at least a portion of the top surface.

### BRIEF DESCRIPTION OF THE DRAWINGS

FIG. 1 is a graph of a typical solar spectrum at sea level in accordance with the present disclosure.

FIG. 2 illustrates an example of a thermal management system comprising a base component and an overhang component in accordance with the present disclosure.

FIG. 3 illustrates an example of a thermal management system comprising a base component, an upright component, and an overhang component in accordance with the present disclosure.

FIG. 4a illustrates an example of a thermal management system including high thermal conductive layers in accordance with the present disclosure.

FIG. 4b illustrates an example of a thermal management system including heat pipes in accordance with the present disclosure.

FIG. 5 illustrates an example of a thermal management system comprising a photovoltaic cell in thermal communication with a bottom surface of a base component in accordance with the present disclosure.

FIGS. 6a-g illustrate several examples of the geometry of an overhang component in accordance with the present disclosure.

### DETAILED DESCRIPTION

Heat can enter a PV cell according to two mechanisms. In one, the PV cell may absorb light having an energy above the band-gap energy of the cell. As a result, the electrons may be promoted across the band-gap from the HOMO (highest occupied molecular orbital) to the LUMO (lowest unoccupied molecular orbital) by absorbing the energy. Energy in excess of the band-gap may be converted into heat energy that may be absorbed by the PV cell matrix. In the second mechanism, the PV cell may absorb light having an energy less than the band-gap energy. In this situation, no electrons may be promoted across the band gap, and the energy may simply be absorbed by the PV cell matrix as heat.

In order to improve the PV cell efficiency, the heat of the PV cell matrix should be dissipated. Heat dissipation may be accomplished by providing a thermal sink for the heat, such as a device with fins, which may be air or fluid cooled. The PV cell may be placed in thermal communication with the thermal sink, and the heat may be transferred to the cooling fluid in this manner.

Additionally, the thermal load on the PV cell may be reduced by preventing heat from being introduced into the cell initially. For example, a structure may be designed to prevent light having an energy below the band gap energy from being absorbed by the cell. Light in this energy range may produce no useable electrical current, and may simply add to the initial heat load. Such a blocking structure may therefore reduce the initial heat load on the cell and improve its efficiency.

Disclosed below are systems and methods for manufacturing a thermal management system for PV cells that reduces the initial thermal load on the cells, as well as dissipates the thermal load developed in the PV cells during operation.

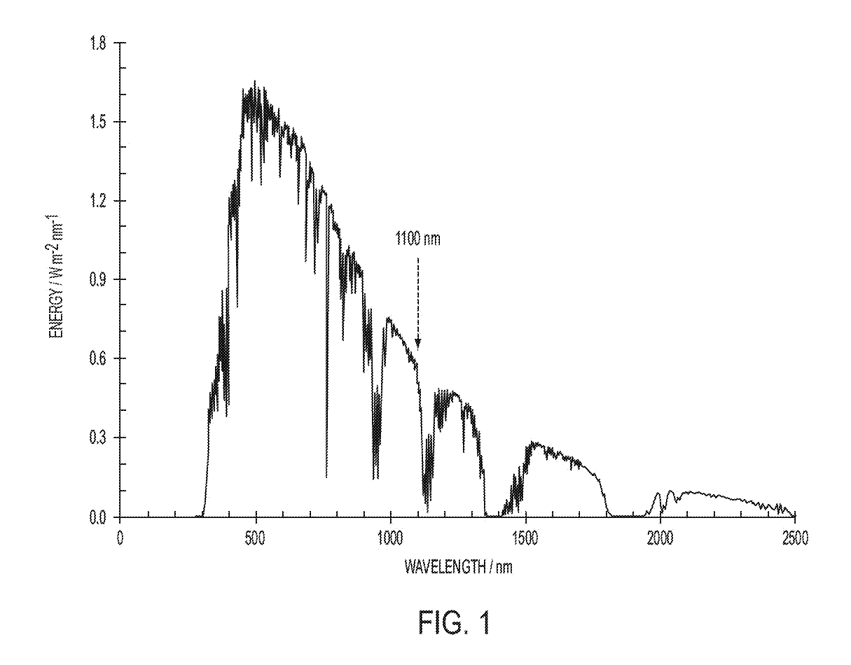

FIG. 1 is a graph of the typical energy spectrum of sunlight at approximately sea level. In general, the solar emission spectrum is that of a black body radiator, with troughs representing energy absorbance due to atmospheric components, most notably water. A crystalline silicon PV cell may be able to convert light to electric current for light having a wavelength of about 400 nm (at the UV end of the solar spectrum) to about 1100 nm (the band-gap energy of silicon). For crystalline silicon, light having a wavelength greater than the band-gap energy (corresponding to lower energy photons) may not be able to promote electrons across the band-gap, and therefore may not produce current. It may be seen in FIG. 1 that there is a significant amount of solar energy having wavelengths greater than the silicon band gap energy. Therefore, a structure designed to prevent the IR solar energy having energy below the band-gap energy from impinging on the cell may help reduce the initial thermal load on the cell.

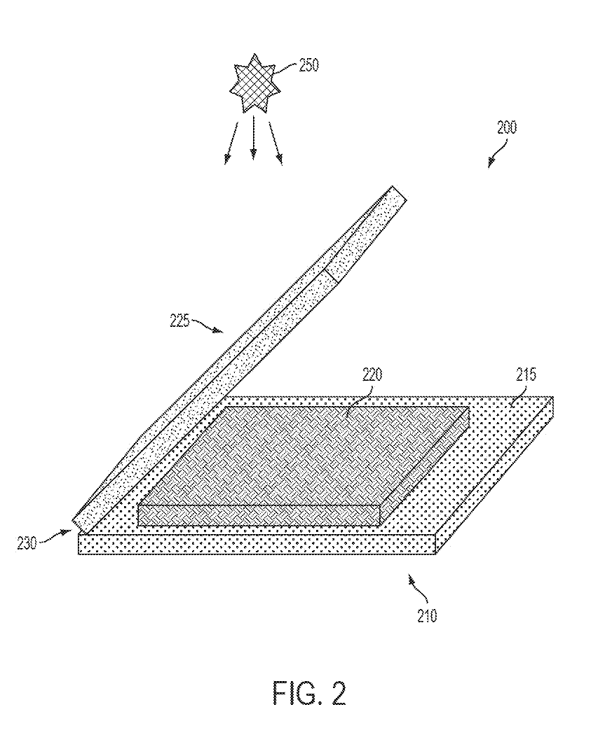

FIG. 2 illustrates one embodiment of a PV cell thermal management system 200. The system 200 may comprise a base component 210 having a top surface 215. At least some portion of at least one PV cell 220 may be in thermal communication with the base component 210. In one embodiment, the PV cell 220 may be in thermal communication with the top surface 215 of the base component 210. An overhang component 225 in thermal communication with the base portion may be disposed above and project over at least some portion of the top surface 215 of the base component 210. The overhang component 225 may form a thermal contact 230 with the base component 210, thereby allowing a significant amount of the heat generated by the PV cell 220 to be dissipated into the overhang portion 225. The heat may then be transferred from the overhang component 225 to air or another cooling fluid which may contact the overhang component 225. The overhang may thus act in one cooling capacity as a heat sink fin. It may be appreciated that an overhang component 225 disposed above and projecting over the base portion 210 may also be disposed above and project over at least a portion of the one or more one photovoltaic cells 220 placed in thermal communication with the base component 210 as illustrated in FIG. 2.

The base component 210 may be formed from any material with good thermal conducting properties. In one non-limiting example, plastic materials may have a thermal conductivity on the order of about 0.1 W/mK. In another non-limiting example, glasses may have a thermal conductivity on the order of about 1 W/mK. In still another non-limiting example, metals may have a thermal conductivity of about 10W/mK to about 400 W/mK. Some non-limiting examples of such material may include a metal, glass, quartz, crystal, alumina, sapphire, polyethylene, acrylic, poly carbonate, and polyethylene terephthalate. In some embodiments, the base component may have a width of about 1 cm to about 1 m, a length of about 1 cm to about 1 m, and a thickness of about 1 mm to about 4 cm. Examples of base component widths may include about 1 cm, about 5 cm, about 10 cm, about 50 cm, about 100 cm, about 200 cm, about 400 cm, about 600 cm, about 800 cm, about 1 m, and ranges between any two of these values. Examples of base component lengths may include about 1 cm, about 5 cm, about 10 cm, about 50 cm, about 100 cm, about 200 cm, about 400 cm, about 600 cm, about 800 cm, about 1 m, and ranges between any two of these values. Examples of base component thickness may include about 1 mm, about 2 mm, about 5 mm, about 1 cm, about 2 cm, about 3 cm, about 4 cm, and ranges between any two of these values. In one non-limiting example, the base may have a width of about 3 cm, a length of about 1 m, and a thickness of about 2.5 cm.

The overhang component 225 may lie in the illumination path of the solar radiation 250. The overhang component 225 may be made from a material substantially opaque to radiation having energy less than about the band-gap energy of the PV cell, while at the same time being substantially transparent to energy greater than about the band-gap energy. In this manner, the overhang component may prevent the cell from absorbing excess heat from the sunlight, while allowing only light having energy useful in generating a photovoltaic current to illuminate the PV cell. Non-limiting examples of overhang component materials with these optical properties may include polycarbonate, polyacrylate, and polymethyl methacrylate. Without limitation, the band-gap energy may have a wavelength of about 700 nm to about 1300 nm, depending on the type of PV cell. Examples of band-gap energies may include about 700 nm, 800 nm, 900 nm, 1000 nm, 1100 nm, 1200 nm, 1300 nm, and ranges between any two of these values. As one non-limiting example, the band-gap energy of silicon may have a wavelength of about 1100 nm.

In one embodiment, the overhang component 225 may be considered substantially transparent to radiation with an energy greater that about the band-gap energy if it has a percent transmittance of greater than about 70%. Examples of substantial transparency may include a percent transmittance greater than about 75%, greater than about 80%, greater than about 85%, greater than about 90%, greater than about 95%, about 100%, and ranges between any two of these values. In one embodiment, the overhang component 225 may be considered substantially opaque to radiation with an energy less that about the band-gap energy if it has a percent transmittance of less than about 30%. Examples of substantial opacity may include a percent transmittance less than about 25%, less than about 20%, less than about 15%, less than about 10%, less than about 5%, about 0%, and ranges between any two of these values. In another embodiment, the overhang component 225 may be considered substantially opaque to radiation with an energy less that about the band-gap energy if it has a percent transmittance of less than about 10%.

In addition, the overhang component 225 may be coated with or otherwise be in contact with an anti-reflecting coating. Non-limiting examples of such anti-reflecting coating may include magnesium fluoride, an acrylic film, a nanoporous organosilicate thin film, surface modified metal oxide nano-particles, and combinations of these materials. Further, the overhang component may include an emissive dye as a material applied to the overhang surface or incorporated into the overhang material. The emissive dye may absorb radiation having an energy greater than about a band-gap energy of a photovoltaic cell and may emit radiation having an energy less than the absorbed energy and greater than about the band-gap energy of the photovoltaic cell. As a non-limiting example, the dye may absorb energy greater than about twice the band-gap energy of the photovoltaic cell. Such a dye may be useful to down-convert high energy UV photons that may damage the PV cell, to lower energy photons that may not prove as destructive. Alternatively, the emissive dye may function to up-convert multiple photons each having an energy less than the band-gap energy, and emit at least one photon at an energy greater than about a band-gap energy of a photovoltaic cell. Such dyes may include, without limitation, 4-(dicyanomethylene)-2-tert-butyl-6-(1,1,7,7,-tetramethyljulolidy-9-enyl)-4H-pyran, Pt-tetraphenyltetrabenzoporphyrin, rhodamine-6G, coumarin-6, or combinations of these materials. It may be understood that such emissive dyes may be used alone or in combination, and that combinations of dyes may be incorporated into the overhang component. Thus, one embodiment of a dye combination for up-converting lower energy photons may include a combination of Pt(II)-octaethylporphyrin (photon receiver) and 9,10-diphenylanthracene (photon emitter).

In some embodiments, the overhang component 225 may be about 1 cm to about 30 cm wide, about 1 cm to about 10 m long, and about 1 mm to about 4 cm thick. Examples of overhang component widths may include about 1 cm, about 5 cm, about 10 cm, about 15 cm, about 20 cm, about 25 cm, about 30 cm, and ranges between any two of these values. Examples of overhang component lengths may include about 1 cm, about 5 cm, about 10 cm, about 50 cm, about 100 cm, about 200 cm, about 400 cm, about 600 cm, about 800 cm, about 1 m, about 2 m, about 5 m, about 10 m, and ranges between any two of these values. Examples of overhang component thickness may include about 1 mm, about 2 mm, about 5 mm, about 1 cm, about 2 cm, about 3 cm, about 4 cm, and ranges between any two of these values. In one non-limiting example, the overhang component may be about 10 cm wide, about 1 m long, and about 5 mm thick.

As the overhang component 225 may be disposed above and project over the base component 210, the overhang component may form an angle with respect to the base component. Such an angle may be about 0 degrees (0 rad) to about 80 degrees (1.4 rad). Examples of overhang component angles with respect to the base component may include about 0 degrees (0 rad), about 10 degrees (0.17 rad), about 20 degrees (0.35 rad), about 40 degrees (0.7 rad), about 60 degrees (1.05 rad), about 80 degrees (1.4 rad), and ranges between any two of these values. In one non-limiting example, the overhang component may form an angle with respect to the base component of about 50 degrees (0.87 rad).

It may be understood that the base component 210 may comprise a material that differs from the material comprising the overhang component 225. Alternatively, the base component and overhang component may be made of the same material.

While FIG. 2 illustrates a single PV cell 220 in thermal communication with the base component 210, it may be understood that multiple cells may be placed in contact with a single heat management system base component. The number of PV cells may be about 1 photovoltaic cell to about 1000 cells. Examples of the number of PV cells in thermal communication with a base component may include about 1 cell, about 5 cells, about 10 cells, about 50 cells, about 100 cells, about 200 cells, about 400 cells, about 600 cells, about 800 cells, about 1000 cells, and ranges between any two of these values. In one non-limiting example, about 20 photovoltaic cells may be in thermal communication with a base component. It may be understood that no restriction is implied regarding the distribution of PV cells on the base component. Thus, the cells may be arranged in a linear array, in an n×m matrix of cells (where “n” and “m” are integers), in an array with a non-uniform number of cells in each row or each column, in a non-linear distribution, or a random distribution.

Any type of suitable photovoltaic cell may be used with the thermal management system disclosed above. Non-limiting examples of such PV cell may include monocrystalline silicon, polycrystalline silicon, a homojunction thin film, and a heterojunction thin film. Specific examples of such cells may include, without limitation, CdTe, CaInS, InGaAs, GaInAr, CuInGaSe, fullerene compositions, phtalocyanine compositions, poly(phenylene vinylene) compositions, and perylene compositions. Combinations of these materials into more complex PV cells are also possible.

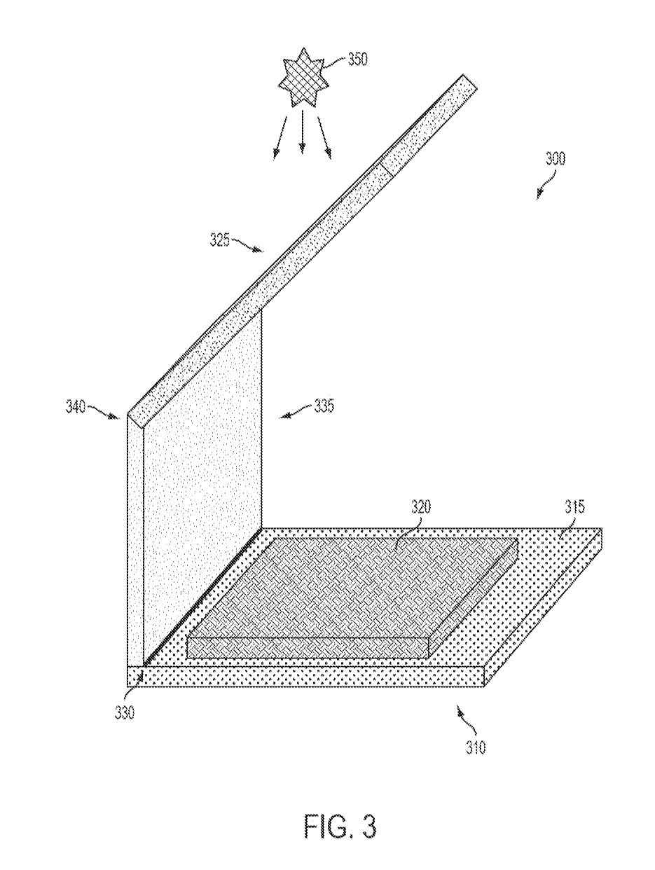

Another embodiment of a thermal management system 300 for PV cells is illustrated in FIG. 3. The thermal management system 300 is similar to that depicted in FIG. 2. The embodiment illustrated in FIG. 3 includes a base component 310 with a top surface 315. The base component may also be in thermal communication with at least one PV cell 320. Additionally, an overhang component 325 is illustrated that is disposed above and projects over at least a portion of the top surface 315 of the base component 310. System 300 also includes an upright component 335 between the overhang component 325 and the base component 310, forming one thermal contact 340 with the overhang component 325, and a second thermal contact 330 with the base component 310. While the upright component 335 may raise the overhang component 325 above the base component 310, the overhang component 325 may still be held in a position so that incident solar radiation 350 may impinge at least in part on the overhang component 325.

Similar to the embodiment illustrated in FIG. 2, the overhang component 325 may be disposed above and project over the base component 310. For the embodiment illustrated in FIG. 3, the overhang component 325 may form an angle with respect to the upright component 335. Such an angle may be about 0 degrees (0 rad) to about 170 degrees (2.79 rad). Examples of overhang component angles with respect to the base component may include about 0 degrees (0 rad), about 10 degrees (0.17 rad), about 20 degrees (0.35 rad), about 50 degrees (0.87 rad), about 75 degrees (1.31 rad), about 100 degrees (1.74 rad), about 125 degrees (2.18 rad), about 150 degrees (2.62 rad), about 170 degrees (2.79 rad), and ranges between any two of these values. In one non-limiting example, the overhang component may form an angle with respect to the upright component of about 140 degrees (2.44 rad).

In some embodiments, the upright component 335 may be about 1 mm to about 3 cm wide, about 1 cm to about 10 m long, and about 1 cm to about 1 m high. Examples of upright component widths may include about 1 mm, about 5 mm, about 1 cm, about 1.5 cm, about 2 cm, about 2.5 cm, about 3 cm, and ranges between any two of these values. Examples of upright component lengths may include about 1 cm, about 5 cm, about 10 cm, about 50 cm, about 100 cm, about 200 cm, about 400 cm, about 600 cm, about 800 cm, about 1 m, about 2 m, about 5 m, about 10 m, and ranges between any two of these values. Examples of upright component heights may include about 1 cm, about 2 cm, about 5 cm, about 10 cm, about 20 cm, about 50 cm, about 100 cm, about 200 cm, about 500 cm, about 750 cm, about 1 m, and ranges between any two of these values. In one non-limiting example, the upright component may be about 10 cm wide, about 1 m long, and about 13 cm high. Although FIG. 3 appears to illustrate that upright component 335 forms about a 90 degree (1.57 rad) angle with respect to base component 310, it should be understood that the angle between the upright component 335 and base component 310 may be any angle capable of supporting the upright component 335 and the overhang component 325, and further permitting the overhang component 325 to be disposed above and project over the base component 310.

It may be appreciated that features associated with the overhang component in FIG. 2, including the type of overhang material, light reflective material, and emissive dyes, may apply as well to the overhang component 325 in FIG. 3. In addition, the materials comprising the base component 310 and upright component 335 may include materials disclosed above with respect to the base component and/or overhang component illustrated by FIG. 2.

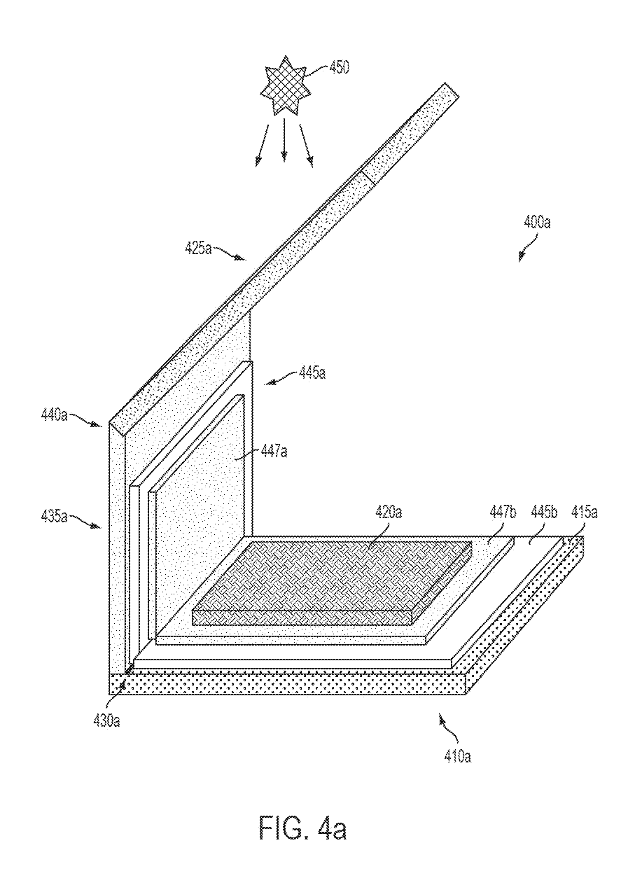

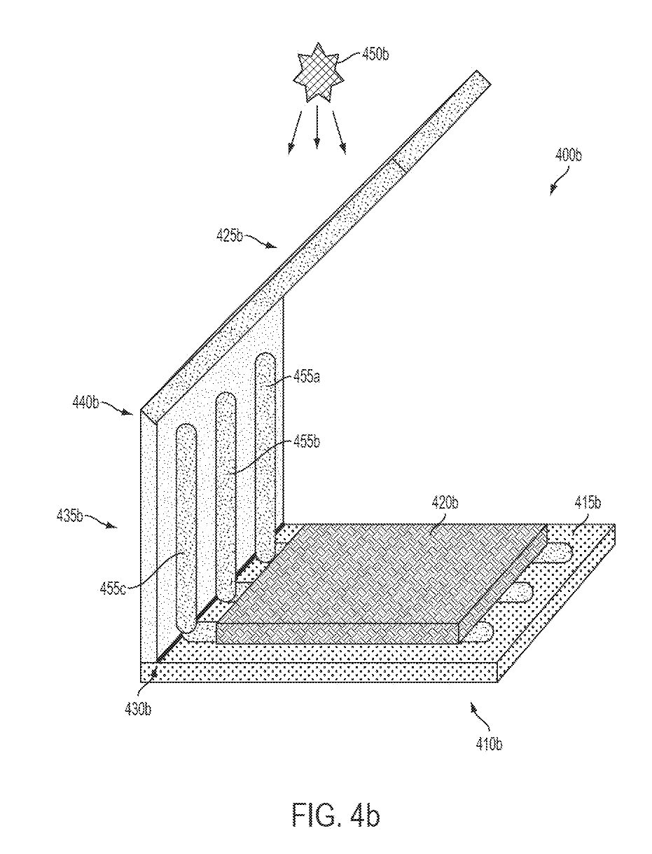

FIGS. 4a and b illustrate additional components to the heat management system disclosed above with respect to FIG. 3 and designed to improve the thermal transfer from a PV cell to an overhang component.

FIG. 4a illustrates an embodiment of a thermal management system 400a comprising a base component 410a that may be in thermal communication 430a with an upright component 435a. The upright component 435a may further be in thermal communication 440a with an overhang component 425a. Unlike the configuration illustrated in FIG. 3, PV cell 420a in FIG. 4a may not be in direct thermal communication with base component 410a via top surface 415a. Instead, PV cell 420a may be in direct thermal communication with one or more layers of a high thermal conducting material or materials 447b and/or 445b. The high thermal conducting material(s) may efficiently conduct heat from the PV cell 420a to base component 410a. Alternatively, the one or more layers of high thermal conducting materials 447b and/or 445b in thermal communication with the base component 410a may further be in thermal communication with equivalent high thermal conducting materials 447a and/or 445a, respectively, associated with the upright component 435a. Although the high thermal conducting materials as layered structures 447b and 445b on the base component 410a are described separately from the equivalent materials forming layered structures 447a and 445a on the upright component 435a, it may be appreciated that the layers may be fabricated as continuous layers. Thus one layer may be fabricated as a continuous layer comprising 445a and 445b, and a second layer may be fabricated as a continuous layer comprising 447a and 447b.

It may be appreciated that, although two layers are illustrated in FIG. 4a, the number of high thermal conducting material layers may include any number required by an application. It may also be appreciated that the high thermal conducting material may be provided in any shape or size that may improve thermal conductivity from the PV cell 420a. Although flat continuous rectangular layers are illustrated in FIG. 4a, such an arrangement of the high thermal conducting material should not be taken as limiting. Thus, the high thermal conducting material may have rectangular, curved, wavy, angular, or ribbon-like features on the surfaces to which they may adhere. Additionally, although FIG. 4a illustrates the high thermal conducting material in direct physical contact with base component 410a and upright 435a, such material may also be in thermal and/or physical contact with overhang component 425a.

The high thermal conducting material, for example comprising 447a, 447b, 445a, and 445b, may comprise one or more of chemical vapor deposition diamond, carbon nanotubes, graphene film, glass, silicon carbide, transparent metal oxides, indium tin oxide, or their composites. In one non-limiting embodiment, the high thermal conducting material may comprise at least one layer of a transparent metal less than about 50 nm thick. In another non-limiting embodiment the high thermal conducting material may comprise at least one layer of silver about 10 nm thick. In yet another embodiment the high thermal conducting material may comprise at least one layer of glass about 2 mm to about 10 mm thick. Examples of the thickness of the glass layer may include about 2 mm, about 4 mm, about 6 mm, about 8 mm, about 10 mm, and ranges between any two of these values. As one non-limiting example, the high thermal conducting material may comprise at least one layer of glass about 2 mm thick.

As illustrated in FIG. 4a, multiple layers of high thermal conducting material may be used, in which one layer is placed in thermal communication with another. As a non-limiting example, a layer of chemical vapor deposition diamond, as layers 447a and 447b may be deposited over and placed in thermal communication with a layer of glass, as layers 445a and 445b. The chemical vapor deposition diamond layer may be about 100 μm to about 200μm thick. Examples of the thickness of the chemical vapor deposition diamond layer may include about 100 μm, about 120 μm, about 140 μm, about 160 μm, about 180 μm, about 200 μm, and ranges between any two of these values. In one non-limiting example, the chemical vapor deposition diamond layer may be about 100 μm thick. Although FIG. 4a illustrates an embodiment in which a single high thermal conducting material such as layer 447b is completely in physical and thermal communication with a second high thermal conducting material such as layer 445b, it may be appreciated that only a portion of the first layer may be in physical and/or thermal communication with the second layer. The geometries of each layer may be determined by the process by which it is fabricated, the specifics of the material used, the overall geometry of the thermal management system, the size, shape, composition, or number of PV cells, or other thermal or physical constraints that may be imposed according to materials and/or manufacture.

FIG. 4b illustrates another embodiment of a thermal management system 400b including the use of one or more heat pipes for improved thermal transfer. In one non-limiting embodiment, PV cell 420b may be in thermal communication with heat pipes 455a-c. The heat pipes 455a-c may be in thermal communication with base component 410b and upright component 435b. Although not illustrated in FIG. 4b, heat pipes 455a-c may further be in thermal communication with overhang component 425b. The thermal heat pipes 455a-c may be disposed on top of base component 410b and in thermal communication with top surface 415b. Alternatively, the heat pipes 455a-c may be embedded within the material comprising base component 410b. Similarly, heat pipes 455a-c may contact upright component 435b on a surface or may be embedded within the upright component material.

In one non-limiting embodiment, the one or more heat pipes 455a-c may comprise a transparent high thermal conductivity material as an encapsulating exterior component, a coolant within the encapsulating exterior component, and a capillary system disposed within the exterior component and in thermal communication with the coolant. As non-limiting examples, the transparent high thermal conductivity material may comprise one or more of glass, silicon carbide, transparent metal oxides, indium tin oxide, or composites of these materials. Further non-limiting examples of the heat pipes may include a coolant comprising one or more of ethanol, methanol, mercury, ammonia, water, or combinations of these materials. Additionally, the capillary systems of the heat pipes may comprise one or more of a metal mesh wick, a grooved wick, a sintered metal wick, or combinations of such structures.

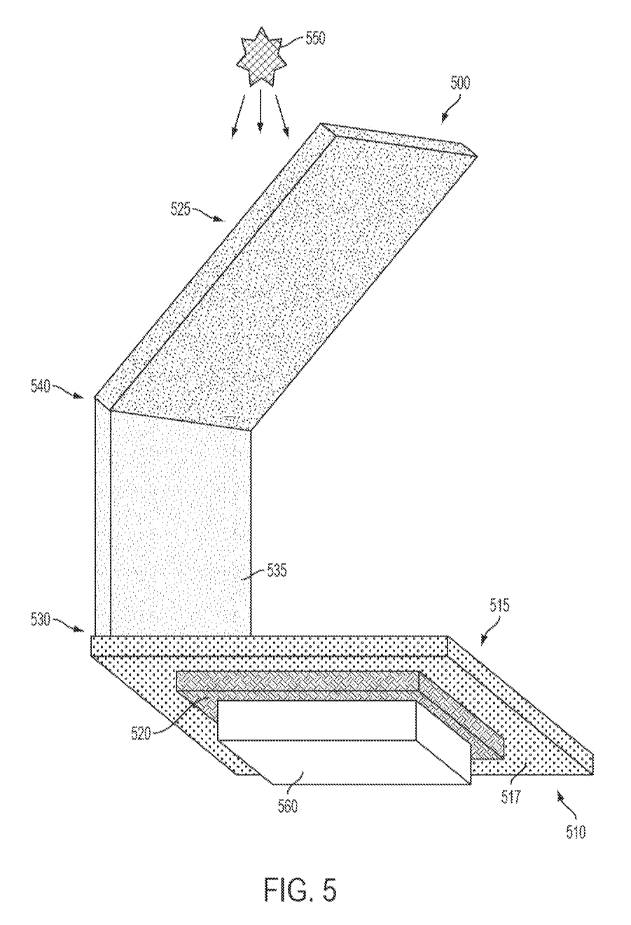

FIG. 5 illustrates yet another embodiment of a thermal management system for one or more PV cells 500. Similar to embodiments disclosed above, the system may comprise a base component 510 having a top surface 515 and in thermal communication with an upright component 535. The upright component 535 may further be in thermal communication with overhang component 525. As illustrated in FIG. 5, the one or more PV cells 520 may be in communication with a bottom surface 517 of the base component. It may be appreciated that the PV cell 520 may form a thermal contact to the bottom surface 517 via a top surface of the PV cell (not shown), and that the PV cell 520 may directly contact the base component 510 or may be in contact with any of a number of high thermal conducting materials placed between the PV cell top surface and the base component bottom surface 517.

Additional thermal transfer may be accomplished by contacting a bottom surface of the PV cell (not shown) with a heat sink 560. Additional high thermal conducting materials may be placed between the bottom surface of the PV cell and the heat sink 560. The heat sink 560 may comprise any material or materials suitable for high thermal transfer to the heat sink Additionally, the heat sink 560 may have a geometry conducive to good thermal transfer to a fluid such as air that may contact it. For example, the heat sink 560 may comprise a simple block, as illustrated in FIG. 5. Alternatively, the heat sink may have a mounting base (not shown) in thermal communication with the bottom surface of the one or more photovoltaic cells, and a fin structure (not shown) in thermal communication with the mounting base. The fin structure may be made of one or more fins for increased surface area.

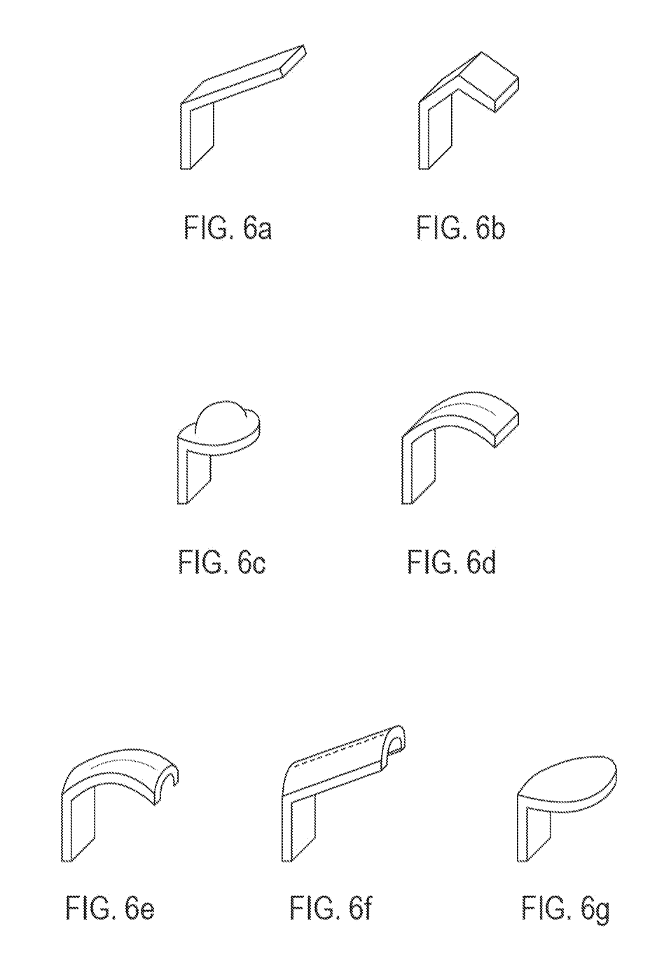

While overhang components 225 (FIG. 2), 325 (FIG. 3), 425a (FIG. 4a), 425b (FIGS. 4b), and 525 (FIG. 5) are all illustrated as having a flat planar shape, it may be understood that the overhang component may take on any suitable geometry to provide sufficient coverage over at least part of either the base component, the one or more PV cells, or both. The geometry may also be chosen specifically to provide sufficient structural support against rain, wind, dust, and other climatic factors. FIGS. 6a-g illustrate several possible non-limiting examples of such geometries. FIG. 6a illustrates an embodiment comprising a simple flat planar structure. FIG. 6b illustrates an embodiment comprising an angled flat structure, similar to a roof-line. FIG. 6c illustrates an embodiment of a domed overhang component. FIG. 6d illustrates an embodiment of an arched structure. FIG. 6e illustrates an embodiment of a scalloped overhang. FIG. 6f illustrates an embodiment of an arc structure for an overhang component. FIG. 6g illustrates an embodiment of a flat overhang structure in the shape of a circle, ellipse, or other conic section. It may be appreciated that a wide variety of shapes and geometries are therefore anticipated by this disclosure.

The heat management devices disclosed above may be used in a method to manage and reduce heat in one or more active photovoltaic cell. The method my include providing at least one photovoltaic cell, providing at least one thermal management device, contacting at least a portion of the one or more photovoltaic cells to form a thermal contact with the thermal management device, and exposing the thermal management device to a fluid thereby transferring an amount of heat from the thermal management device to the fluid. The thermal management device may include a base component having a top surface and an overhang component in thermal communication with the base component. The overhang component may form a thermal contact with the base by means of one or more of an adhesive, chemical welding, heat welding, spot welding, and/or a high thermal conductivity tape. Alternatively, the overhang component may make a thermal contact with the base component by virtue of the two components being fabricated as a single unit. The overhang component may be disposed above and project over at least a portion of the one or more photovoltaic cells.

One or more photovoltaic cells may form a thermal contact with either the top surface or a bottom surface of the base component. Some non-limiting examples of such a thermal contact may include gluing the PV cell to the base component with a heat transfer adhesive, chemical welding, heat welding, spot welding, and/or through the use of a high thermal conductivity tape. As non-limiting examples, the adhesives may include one or more of cyanoacrylates, acrylic resins, toughened acrylics, anaerobic locking compounds, multi-component adhesives, epoxies, polyurethanes, silicones, phenolics, polyimides, hot melts, thermoplastics, plastisols, rubber adhesives, polyvinyl acetate and pressure-sensitive adhesives, neoprene and nitrile based contact adhesives. As disclosed above, the overhang component may include a material substantially transparent to a radiation having an energy greater than about the band-gap energy of the one or more photovoltaic cell and substantially opaque to a radiation having an energy less than about the band-gap energy of the one photovoltaic cell(s). Further, the overhang may include an anti-reflecting coating or an emissive dye.

As illustrated in FIGS. 3-5, the thermal management device may also include an upright component having a first end in thermal communication with at least a portion of the overhang component, and a second end that may be in thermal communication with at least a portion of the base component. In one example, the base component, upright component, and overhang component may be fabricated separately, and the three components may then be assembled to form thermal contacts between the base component and the upright component, and the upright component and the overhang component. The connections may be made by gluing, chemical welding, heat welding, spot welding, and/or through the use of a high thermal conductivity tape. Adhesives may include one or more of cyanoacrylates, acrylic resins, toughened acrylics, anaerobic locking compounds, multi-component adhesives, epoxies, polyurethanes, silicones, phenolics, polyimides, hot melts, thermoplastics, plastisols, rubber adhesives, polyvinyl acetate and pressure-sensitive adhesives, neoprene and nitrile based contact adhesives. In an alternative embodiment, the base component, upright component, and overhang component may be fabricated as a single piece.

A structure similar to that disclosed in FIGS. 4a-b may also be used, in which one or more high thermal conducting materials may be interposed between the PV cell and at least one of the base, the upright, and/or the overhang components. The high thermal conducting materials may constitute one or more layers as illustrated in FIG. 4a, or heat pipes as illustrated in FIG. 4b. It may be understood, that a system with multiple high thermal conducting layers may have those layers in mutual physical and/or thermal communication.

When the thermal management device is exposed to a fluid, the fluid may flow passively in thermal communication with the thermal management device (such as a wind). Alternative, the fluid may be actively directed to flow in thermal communication with the thermal management device (a fan or water cooling system with a pump, as non-limiting examples).

The thermal management device as disclosed above may be manufactured according to a number of different methods. In one embodiment, the base component and the overhang component may be separately fabricated. The overhang component may be fabricated from a heat conducting material substantially transparent to a radiation having an energy greater than about a band-gap energy of the at least one photovoltaic cell, and substantially opaque to a radiation having an energy less than about the band-gap energy of the at least one photovoltaic cell. The base component may be fabricated from the same material as the overhang, a different heat conducting material, or a combination of the two. The overhang component may be disposed above and at least partially over the base component, and the two components may be fixed together to maintain a thermal contact between the two. The two components may be fabricated by any suitable method including molding, extruding, cutting, shaping, deposition, and milling. The method may also include contacting or coating the upright component with a reflective coating, and the upright component may also include an emissive dye.

In another embodiment, an upright component may be fabricated from either the material used for fabricating the overhang component, a different heat conducting material, or a combination of the two. The upright component may be placed in thermal communication with the overhang component at one end and with the base component at another end. The thermal contacts between the upright component and the overhang component, and the upright component and the base component may be accomplished by any suitable method including gluing, chemical welding, heat welding, spot welding, and/or through the use of a high thermal conductivity tape. One or more high thermal conducting materials, including but not limited to material layers and heat pipes, may be placed in thermal communication with the thermal management system after it is assembled. The high thermal conducting materials may contact one or more of the base component, the overhang component, and the upright component, if one is included in the thermal management system.

As disclosed above, in one embodiment, the thermal management device may comprise an overhang component and a base component having a top surface. In another embodiment, the thermal management device may comprise an overhang component, an upright component, and a base component having a top surface. Either or both of these embodiments may be fabricated from a single heat conducting material substantially transparent to a radiation having an energy greater than about a band-gap energy of the at least one photovoltaic cell, and substantially opaque to a radiation having an energy less than about the band-gap energy of at least one photovoltaic cell. In either or both embodiments, the overhang component may be fabricated so that it is disposed above and projects over at least a portion of the top surface. The method by which either embodiment or both embodiments may be fabricated may comprise one or more of molding, extruding, cutting, shaping, deposition, and milling.

In addition, either or both thermal management devices may include an anti-reflective coating associated with the overhang component. Further, either or both thermal management devices may include an emissive dye associated with the overhang component. Additional high thermal conducting materials may also be applied to the thermal management devices either as layers or as heat pipes.

### EXAMPLES

### Example 1

### Thermal Management Device for PV Cells

A thermal management device may be fabricated having a base component, an upright component, and an overhang component. The device may be fabricated from a single 0.944 inch (2.4 cm) thick acrylic sheet overlaid with a high transmission acrylic sheet having a coating providing less than about 5% reflectance. The base component may be about 8 inches (20 cm) wide, and about 40 inches (1 m) long. The upright component may be perpendicular to the base component and about 5 inches (13 cm) high and about 40 inches (1 m) long. The overhang component may form an angle of about 135 degrees (2.35 rad) with respect to the upright component and may further be about 12 inches (30 cm) wide and about 40 inches (1 m) long. Sheets of 2 mm thick glass may be cut and fastened together to form an ‘L’ shaped component such as by fusing the pieces together. The ‘L’ shaped glass component may be coated with a layer about 100 μm thick of chemical vapor deposition (“CVD”) diamond. The CVD diamond coated glass components may then be affixed to the top surface of the base component and inner surface of the upright component so that the CVD diamond surface may be exposed. In one non-limiting embodiment, the coated glass may be affixed onto the base component and upright component through the use of an adhesive. In another embodiment, the coated glass may be affixed onto the base component and the upright component by heating the base and upright components until they soften, thereby allowing the coated glass to adhere directly to the base and upright components. A silicon photovoltaic cell array may be placed in thermal communication with the CVD diamond layer on the base by means of an adhesive, the array measuring about 6.8 inches (17.35 cm) wide and about 40 inches (1 m) long.

### Example 2

### Use of a Thermal Management Device for PV Cells

The thermal management device disclosed in Example 1, above, may reduce the amount of solar radiation having wavelengths greater than the band-gap energy wavelength. An acrylic sheet about 1 inch (2.5 cm) thick may have a percent transmittance equal to or greater than 80% for solar radiation having a wavelength of about 410 nm to about 1100 nm. Except for a high transmittance peak for radiation at around 1525 nm, the acrylic may have a percent transmittance less than or equal to about 25% for radiation having a wavelength greater than about 1300 nm. An acrylic sheet coated with an antireflective coating providing less than about 5% reflectance may increase the percent transmission of radiation having a wavelength of about 400 nm to about 750 nm to over 95%. As a result, approximately about 70% of the solar radiation having a wavelength greater than about 1100 nm may be absorbed and dissipated by the overhang component. Thus, only about 30% of the solar spectrum energy that may not result in direct current production may reach the PV cell. While the acrylic overhang material may have some absorbance in the “productive” range of the solar spectrum (400 nm to the band gap energy of about 1100 nm for silicon PV devices), about 97% of the radiation in the “productive” range may still impinge on the PV cells.

### Example 3

### Method of Fabricating a Thermal Management Device for PV Cells

A thermal management device essentially as disclosed in Example 1 may be fabricated by casting the base component, upright component, and overhang component as a single structure out of an acrylic material. A thin sheet of glass substrate about 2 mm thick may be coated with a layer about 100 μm thick of chemical vapor deposition (“CVD”) diamond. The diamond-coated glass may then be cut and fused together to form an ‘L’ shaped component having dimensions to fit against the inner surface of the cast acrylic thermal management device. The coated glass may then be affixed to the cast acrylic thermal management device either by a transparent adhesive or by annealing the acrylic to permit the glass to partially imbed in the body of the device. The PV cells may be affixed onto the CVD diamond surface of the glass substrate on the base structure. An adhesive thermal grease may be used to insure proper thermal contact between the PV cell and the CVD diamond surface.

The present disclosure is not to be limited in terms of the particular embodiments described in this application, which are intended as illustrations of various aspects. Many modifications and variations can be made without departing from its spirit and scope, as will be apparent to those skilled in the art. Functionally equivalent methods and apparatuses within the scope of the disclosure, in addition to those enumerated in this disclosure, will be apparent to those skilled in the art from the foregoing descriptions. Such modifications and variations are intended to fall within the scope of the appended claims. The present disclosure is to be limited only by the terms of the appended claims, along with the full scope of equivalents to which such claims are entitled. It is to be understood that this disclosure is not limited to particular methods, reagents, compounds, or compositions, which can, of course, vary. It is also to be understood that the terminology used in this disclosure is for the purpose of describing particular embodiments only, and is not intended to be limiting.

With respect to the use of substantially any plural and/or singular terms in this disclosure, those having skill in the art can translate from the plural to the singular and/or from the singular to the plural as is appropriate to the context and/or application. The various singular/plural permutations may be expressly set forth in this disclosure for sake of clarity. It will be understood by those within the art that, in general, terms used in this disclosure, and especially in the appended claims (e.g., bodies of the appended claims) are generally intended as “open” terms (e.g., the term “including” should be interpreted as “including but not limited to,” the term “having” should be interpreted as “having at least,” the term “includes” should be interpreted as “includes but is not limited to,” etc.). While various compositions, methods, and devices are described in terms of “comprising” various components or steps (interpreted as meaning “including, but not limited to”), the compositions, methods, and devices can also “consist essentially of” or “consist of” the various components and steps, and such terminology should be interpreted as defining essentially closed-member groups.

It will be further understood by those within the art that if a specific number of an introduced claim recitation is intended, such an intent will be explicitly recited in the claim, and in the absence of such recitation no such intent is present. For example, as an aid to understanding, the following appended claims may contain usage of the introductory phrases “at least one ” and “one or more ” to introduce claim recitations. However, the use of such phrases should not be construed to imply that the introduction of a claim recitation by the indefinite articles “a” or “an” limits any particular claim containing such introduced claim recitation to embodiments containing only one such recitation, even when the same claim includes the introductory phrases “one or more ” or “at least one” and indefinite articles such as “a” or “an” (e.g., “a” and/or “an” should be interpreted to mean “at least one” or “one or more”); the same holds true for the use of definite articles used to introduce claim recitations. In addition, even if a specific number of an introduced claim recitation is explicitly recited, those skilled in the art will recognize that such recitation should be interpreted to mean at least the recited number (e.g., the bare recitation of “two recitations,” without other modifiers, means at least two recitations, or two or more recitations). Furthermore, in those instances where a convention analogous to “at least one of A, B, and C, etc.” is used, in general such a construction is intended in the sense one having skill in the art would understand the convention (e.g., “a system having at least one of A, B, and C” would include but not be limited to systems that have A alone, B alone, C alone, A and B together, A and C together, B and C together, and/or A, B, and C together, etc.). It will be further understood by those within the art that virtually any disjunctive word and/or phrase presenting two or more alternative terms, whether in the description, claims, or drawings, should be understood to contemplate the possibilities of including one of the terms, either of the terms, or both terms. For example, the phrase “A or B” will be understood to include the possibilities of “A” or “B” or “A and B.”

As will be understood by one skilled in the art, for any and all purposes, such as in terms of providing a written description, all ranges disclosed in this disclosure also encompass any and all possible subranges and combinations of subranges thereof. Any listed range can be easily recognized as sufficiently describing and enabling the same range being broken down into at least equal halves, thirds, quarters, fifths, tenths, etc. As a non-limiting example, each range discussed in this disclosure can be readily broken down into a lower third, middle third and upper third, etc. As will also be understood by one skilled in the art all language such as “up to,” “at least,” and the like include the number recited and refer to ranges which can be subsequently broken down into subranges as discussed above. Finally, as will be understood by one skilled in the art, a range includes each individual member.

From the foregoing, it will be appreciated that various embodiments of the present disclosure have been described for purposes of illustration, and that various modifications may be made without departing from the scope and spirit of the present disclosure. Accordingly, the various embodiments disclosed are not intended to be limiting, with the true scope and spirit being indicated by the following claims.

1. A device for managing heat in at least one photovoltaic cell, the device comprising:
a base component having a top surface; and
an overhang component in thermal communication with the base component,
wherein the base component is in thermal communication with at least a portion of the at least one photovoltaic cell, and the overhang component is disposed above and projects over at least a portion of the top surface of the base component.

2.-4. (canceled)

5. The device of claim 1, wherein the overhang component is disposed above and projects over the at least portion of the at least one photovoltaic cell.

6. The device of claim 1, wherein the overhang component comprises a material substantially transparent to a radiation having an energy greater than about a band-gap energy of a photovoltaic cell, and substantially opaque to a radiation having an energy less than about the band-gap energy of the photovoltaic cell.

7.-12. (canceled)

13. The device of claim 1, further comprising an anti-reflecting coating configured to contact at least a portion of the overhang component.

14. (canceled)

15. The device of claim 1, wherein the overhang component further comprises an emissive dye.

16.-22. (canceled)

23. The device of claim 1, wherein the overhang component forms an angle with respect to the base component of about 0 degrees (0 rad) to about 80 degrees (1.4 rad).

24. (canceled)

25. The device of claim 1, wherein the base component comprises a base material, the overhang component comprises an overhang material, and the base material differs from the overhang material.

26. The device of claim 1, wherein the base component comprises a material and the overhang component comprises the material.

27.-30. (canceled)

31. The device of claim 1, wherein the top surface is in thermal communication with the at least portion of the at least one photovoltaic cell.

32. The device of claim 1, wherein the base component further comprises a bottom surface, and the bottom surface is in thermal communication with the at least portion of the at least one photovoltaic cell.

33. The device of claim 32, wherein
the at least one photovoltaic cell has a top surface, and
the top surface of the at least one photovoltaic cell is in thermal communication with the bottom surface of the base component.

34. The device of claim 33, wherein
the at least one photovoltaic cell has a bottom surface, and
the bottom surface of the at least one photovoltaic cell is in thermal communication with a heat sink.

35. (canceled)

36. The device of claim 1, further comprising an upright component having a first end and a second end, wherein the first end is in thermal communication with at least a portion of the overhang component, and the second end is in thermal communication with at least a portion of the base component.

37.-40. (canceled)

41. The device of claim 1, further comprising at least one high thermal conducting material in thermal communication with at least a portion of one or more of the following: the base component, the at least one photovoltaic cell, the overhang component, and an upright component having a first end and a second end, wherein the first end is in thermal communication with at least a portion of the overhang component, and the second end is in thermal communication with at least a portion of the base component.

42. (canceled)

43. The device of claim 41, wherein the at least one high thermal conducting material comprises at least one heat pipe.

44.-47. (canceled)

48. The device of claim 41, wherein the at least one high thermal conducting material comprises at least one layer.

49.-55. (canceled)

56. The device of claim 41, wherein at least a portion of at least a first high thermal conducting material is in thermal communication with at least a portion of at least a second high thermal conducting material.

57. A method of thermal management of at least one photovoltaic cell, the method comprising:
providing at least one photovoltaic cell;
providing at least one thermal management device;
causing at least a portion of the at least one photovoltaic cell to form a thermal contact with the thermal management device; and
exposing the thermal management device to a fluid thereby transferring an amount of heat from the thermal management device to the fluid,
wherein the thermal management device comprises a base component having a top surface, and an overhang component in thermal communication with the base component, and
wherein the overhang component is disposed above and projects over at least a portion of the at least one photovoltaic cell.

58. The method of claim 57, wherein causing at least a portion of at least one photovoltaic cell to form a thermal contact with a thermal management device comprises causing at least a portion of the at least one photovoltaic cell to form a thermal contact with the top surface of the base component.

59. The method of claim 57, wherein causing at least a portion of at least one photovoltaic cell to form a thermal contact with a thermal management device comprises causing at least a portion of the at least one photovoltaic cell to form a thermal contact with a bottom surface of the base component.

60.-62. (canceled)

63. The method of claim 57, further comprising causing at least one high thermal conducting material to form a thermal contact with at least a portion of one or more of the following: the base component, the at least one photovoltaic cell, the overhang component, and an upright component having a first end and a second end, wherein the first end is in thermal communication with at least a portion of the overhang component, and the second end is in thermal communication with at least a portion of the base component.

64. The method of claim 57, further comprising causing at least one first high thermal conducting material to form a thermal contact with at least a portion of at least one second high thermal conducting material.

65. The method of claim 64, further comprising causing the at least one first high thermal conducting material to form a thermal contact with at least a portion of one or more of the following: the base component, the at least one photovoltaic cell, the overhang component, and an upright component having a first end and a second end, wherein the first end is in thermal communication with at least a portion of the overhang component, and the second end is in thermal communication with at least a portion of the base component.

66. The method of claim 64, further comprising causing the at least one second high thermal conducting material to form a thermal contact with at least a portion of one or more of the following: the base component, the at least one photovoltaic cell, the overhang component, and an upright component having a first end and a second end, wherein the first end is in thermal communication with at least a portion of the overhang component, and the second end is in thermal communication with at least a portion of the base component.

67. The method of claim 57, wherein exposing the thermal management device to a fluid comprises allowing a fluid to flow passively in thermal communication with the thermal management device.

68. The method of claim 57, wherein exposing the thermal management device to a fluid comprises directing a fluid to flow in thermal communication with the thermal management device.

69. A method of fabricating a thermal management device for at least one photovoltaic cell, the method comprising:
providing a first heat conducting material;
providing a second heat conducting material substantially transparent to a radiation having an energy greater than about a band-gap energy of the at least one photovoltaic cell, and substantially opaque to a radiation having an energy less than about the band-gap energy of the at least one photovoltaic cell;
fabricating a base component from the first heat conducting material, the second heat conducting material, or a combination thereof, wherein the base component comprises a top surface;
fabricating an overhang component from the second heat conducting material;
thermally contacting the overhang component with the base component; and
disposing the overhang component above and over at least a portion of the top surface.

70.-73. (canceled)

74. The method of claim 69, further comprising:
fabricating an upright component from the first heat conducting material, the second heat conducting material, or a combination thereof, wherein the upright component comprises a first end and a second end;
thermally contacting the first end with at least a portion of the overhang component; and
thermally contacting the second end with at least a portion of the base component.

75. The method of claim 69, further comprising thermally contacting at least one high thermal conducting material with a portion of at least one or more of the following: the base component, the at least one photovoltaic cell, the overhang component, and an upright component comprising a first end and a second end wherein the first end is in thermal communication with the base component, and the second end is in thermal communication with the overhang component.

76.-80. (canceled)

81. A method of fabricating a thermal management device for at least one photovoltaic cell, the method comprising:
providing a heat conducting material substantially transparent to a radiation having an energy greater than about a band-gap energy of the at least one photovoltaic cell, and substantially opaque to a radiation having an energy less than about the band-gap energy of the at least one photovoltaic cell; and
fabricating a combined base, upright, and overhang component from the material, wherein the base component comprises a top surface, wherein the upright component is in thermal communication with the base component and the overhang component, and wherein the overhang component is disposed above and over at least a portion of the top surface.

82.-85. (canceled)
